(19) United States
(12) Patent Application Publication
(10) Pub. No.: US 2013/0109115 A1
(43) Pub. Date: May 2, 2013

(54) METHOD AND JIG FOR MANUFACTURING SEMICONDUCTOR DEVICE

(71) Applicant: Tatsuhiko Nagafuchi, Fukuoka-ken (JP)

(72) Inventor: Tatsuhiko Nagafuchi, Fukuoka-ken (JP)

(73) Assignee: Kabushiki Kaisha Toshiba, Tokyo (JP)

(21) Appl. No.: 13/418,215

(22) Filed: Mar. 12, 2012

(30) Foreign Application Priority Data
Oct. 27, 2011 (JP) 2011-235848

(51) Int. Cl. H01L 31/18; B25B 11/02

(52) U.S. Cl. 438/25; 269/287; 257/E31.095

(57) ABSTRACT

According to an embodiment, a method for manufacturing a semiconductor device includes steps of enveloping a semiconductor chip attached to a lead frame with a resin and mounting a film-like member in a pocket provided in a base portion of a jig. The method further includes steps of making the resin in contact with the film-like member by covering the pocket with the portion of the lead frame having the semiconductor chip fixed thereto, after fixing the lead frame to a movable portion of the jig and moving the movable portion in a direction of the base portion; and curing the resin with the lead frame in a state covering the pocket.

### CROSS-REFERENCE TO RELATED APPLICATIONS

This application is based upon and claims the benefit of priority from Japanese Patent Application No. 2011-235848, filed on Oct. 27, 2011; the entire contents of which are incorporated herein by reference.

### FIELD

Embodiments are related generally to a method and a jig for manufacturing a semiconductor device.

### BACKGROUND

The photocoupler is a kind of semiconductor device, which includes a light emitting element and a light receiving element, and transmits signals via the optical coupling therebetween. Hence, photocouplers are used in circuits in which a primary portion and a secondary portion are electrically isolated from each other. There are various applications for photocouplers, wherein good insulation properties are required between the light emitting element on the primary side and the light receiving element on the secondary side.

For example, the photocoupler is included in a package in which the light emitting element and the light receiving element are enveloped in a single body of transparent resin and a light shielding resin is molded on the outside thereof. Further, an insulation film is interposed between the light emitting element and the light receiving element to increase an isolation voltage between the primary side and the secondary side. However, if the insulation film is misaligned in the manufacturing process, the isolation voltage may be lowered and cracking of the package may occur in some cases. As a result, the manufacturing yield of the photocoupler may be lowered and reliability may be reduced. A method for manufacturing a semiconductor device is therefore required to suppress the misalignment of the insulation film interposed between the light emitting element and the light receiving element and to increase the manufacturing yield.

### BRIEF DESCRIPTION OF THE DRAWINGS

FIGS. 1A and 1B are schematic views illustrating a semiconductor device according to an embodiment;

FIGS. 2A to 2C are schematic views illustrating a lead frame according to the embodiment;

FIGS. 3A and 3B are schematic views illustrating a manufacturing jig according to the embodiment;

FIGS. 4A to 5B are cross-sectional views schematically illustrating a manufacturing process of the semiconductor device according to the embodiment;

FIGS. 6A and 6B are schematic views illustrating a jig according to a variation of the embodiment;

FIGS. 7A and 7B are plan views schematically illustrating part of the jig according to the embodiment;

FIG. 8A and FIG. 8B are schematic views illustrating a semiconductor device according to comparative example;

FIGS. 9A and 9B are schematic views illustrating a manufacturing process of the semiconductor device according to the comparative example.

### DETAILED DESCRIPTION

According to an embodiment, a method for manufacturing a semiconductor device includes steps of enveloping a semiconductor chip attached to a lead frame with a resin and mounting a film-like member in a pocket provided in a base portion of a jig. The method further includes steps of making the resin in contact with the film-like member by covering the pocket with the portion of the lead frame having the semiconductor chip fixed thereto, after fixing the lead frame to a movable portion of the jig and moving the movable portion in a direction of the base portion; and curing the resin with the lead frame in a state covering the pocket.

Embodiments of the invention will now be described with reference to the drawings. Note that the same numerals are applied to constituents that have already appeared in the drawings, and repetitious detailed descriptions of such constituents are omitted. Also, the positional relationships of the constituent elements can on occasion be suitably described using the X-Y perpendicular coordinates illustrated in drawings.

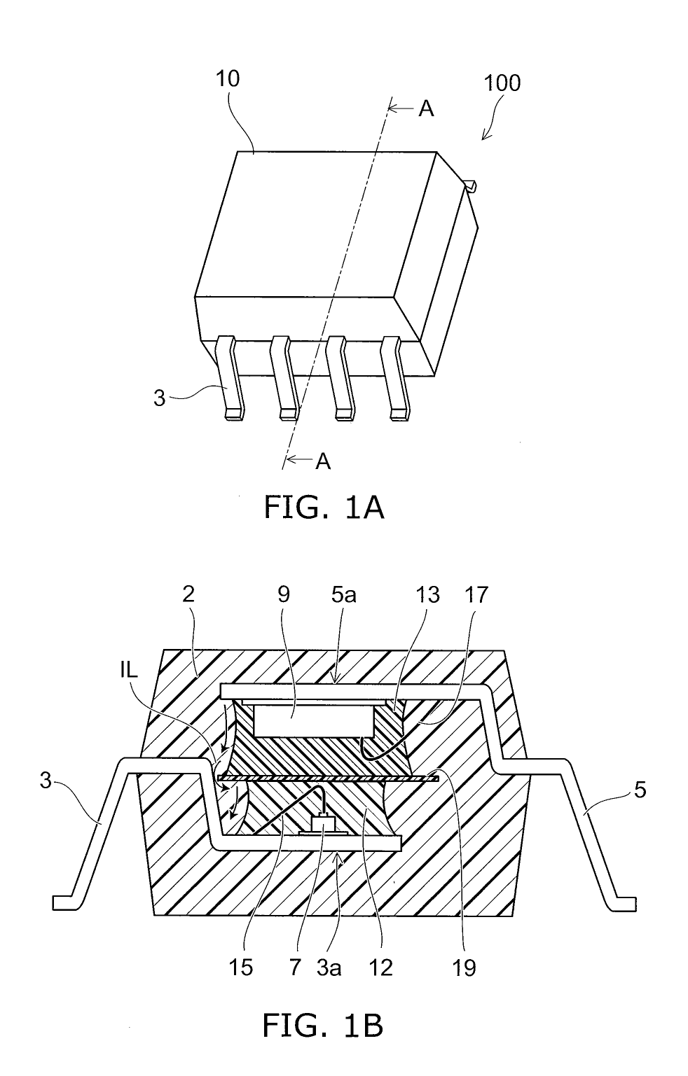

FIGS. 1A and 1B are schematic views illustrating a semiconductor device 100 according to an embodiment. FIG. 1A is a perspective view illustrating an external form of the semiconductor device 100. FIG. 1B is a cross-sectional view taken along line A-A.

The semiconductor device 100 is a photocoupler having semiconductor chips (a light emitting element 7 and a light receiving element 9) enclosed within a molded body 10. Leads 3 electrically connected to the light emitting element 7 and leads 5 electrically connected to the light receiving element 9 extend to both sides of the molded body 10. Here, “leads 3” refers collectively to a plurality of leads on the primary side and “leads 5” refers collectively to a plurality of leads on the secondary side.

The leads 3 include a current terminal and a ground terminal, neither of which is illustrated in the drawings. The light emitting element 7 is fixed to a mount bed 3a that is connected to the ground terminal. The current terminal is electrically connected to an electrode on a top surface of the light emitting element 7 via a metal wire 15.

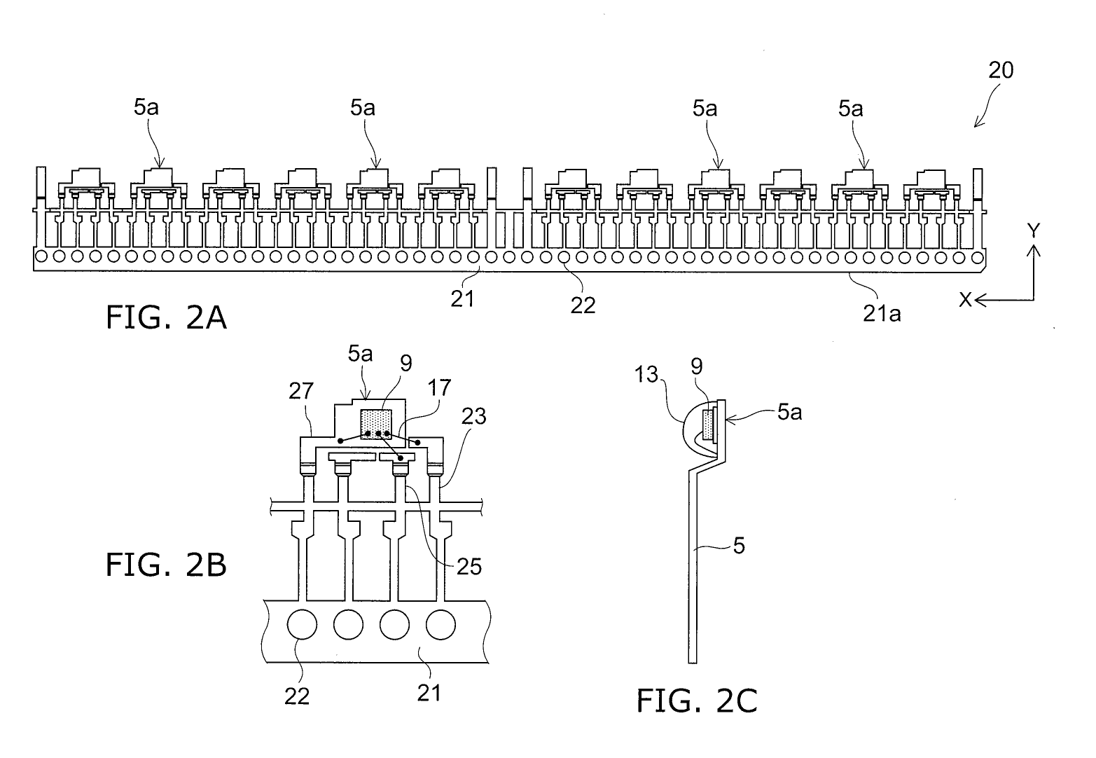

The leads 5 include a power terminal 23, a signal terminal 25 and the ground terminal 27 (see FIG. 2B). The light receiving element 9 is fixedly attached to a mount bed 5a that is connected to the ground terminal 27. The light receiving element 9 is electrically connected to the power terminal 23 and the signal terminal 25 via a plurality of metal wires 17.

As illustrated in FIG. 1B, the light emitting element 7 and the light receiving element 9 are arranged to oppose each other, and light signals emitted by the light emitting element 7 are detected by the light receiving element 9. The light emitting element 7 is enveloped with a transparent resin 12 and the light receiving element 9 is enveloped with a transparent resin 13. Here, the transparent resins 12 and 13 are permeable to at least a portion of the light emitted by the light emitting element 7.

A film-like member (insulation film) 19 is interposed between the transparent resin 12 and the transparent resin 13. The insulation film 19 is arranged so that edges thereof extend outside the transparent resins 12 and 13. The insulation film 19 is permeable to at least a portion of the light emitted by the light emitting element 7.

In addition, the molded body 10 formed from a light shielding resin 2 is provided enveloping ends of the leads 3 to which the light emitting element 7 is fixedly attached, ends of leads 5 to which the light receiving element 9 is fixedly attached, the transparent resins 12 and 13, and the insulation film 19. The light shielding resin 2 shields against external light to improve the photodetection sensitivity of the light receiving element 9.

In the semiconductor device 100, to improve the isolation voltage between the lead 3 on the primary side and the lead 5 on the secondary side, it is desirable to reduce current leakage at an interface between the transparent resin 12 and the light shielding resin 2 and at an interface between the transparent resin 13 and the light shielding resin 2.

In the embodiment, the insulation film 19 is interposed between the transparent resin 12 and the transparent resin 13. The edges of the insulation film 19 extend from the transparent resins 12 and 13 into the light shielding resin 2. Hence, for example, a leakage path I_{L} along the resin interface from the lead 5 to the lead 3 is lengthened by a path along the extended portion of the insulation film 19, and the so-called extended face distance is lengthened. As a result, the insulation resistance between the leads 5 and the leads 3 can be increased. Thus, interposing the insulation film 19 increases the isolation voltage between the primary side and secondary side.

Next, a manufacturing process of the semiconductor device 100 is described with reference to FIG. 2A to FIG. 5B.

FIGS. 2A to 2C are schematic views illustrating a lead frame 20 on the secondary side, to which the light receiving element 9 is fixedly attached. FIG. 2A is a plan view illustrating an external form of the lead frame 20. FIG. 2B is a partial magnified view illustrating a single mount bed 5a and a plurality of secondary side leads. FIG. 2C is a side view of the lead frame 20.

As illustrated in FIG. 2A, in the lead frame 20, a plurality of mount beds 5a is aligned along the X direction, with six of the mount beds 5a constituting a single unit. A plurality of leads corresponding to the mount beds 5a is provided so as to connect to a frame 21. In the frame 21, holes 22 are formed with a constant pitch. The lead frame 20 of this type can, for example, be formed by press processing a plate made of a copper alloy.

As illustrated in FIG. 2B, the light receiving element 9 is fixedly attached to the mount bed 5a using, for example, a silver (Ag) paste. The mount bed 5a is connected to the ground terminal 27. A plurality of metal wires 17 is bonded between electrodes provided on a front surface of the light receiving element 9 and the power terminal 23, the signal terminal 25 and the ground terminal 27, respectively. Thus, the light receiving element 9 and the terminals are electrically connected. The power terminal 23, the signal terminal 25 and the ground terminal 27 will form the secondary side leads 5 which extend outside the molded body 10 (see FIG. 1).

Next, as illustrated in FIG. 2C, the transparent resin 13 that envelops the light receiving element 9 is formed on the mount bet 5a. The transparent resin 13 may, for example, be silicone gel or silicone gum, and be applied in a predetermined quantity by a dispenser.

Next, the insulation film 19 is adhered to the front surface of the transparent resin 13.

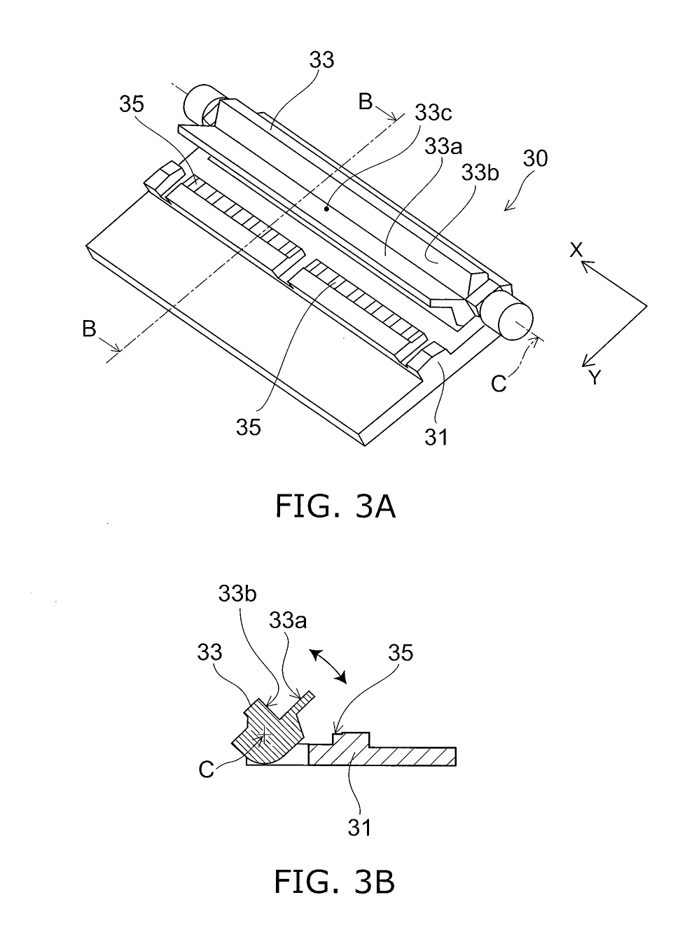

FIGS. 3A and 3B are schematic views illustrating a jig 30 used to adhere the insulation film 19. FIG. 3A is a perspective view illustrating an external form of the jig 30 and FIG. 3B illustrates a cross-section taken along the line B-B.

The jig 30 includes a base portion 31 and a movable portion 33. The base portion 31 has a plurality of pockets 35 on which the insulation films 19 is mounted. The movable portion 33 is, for example, installed so as to be rotatable with respect to the base portion 31 around a rotation axis C that is parallel to the X direction.

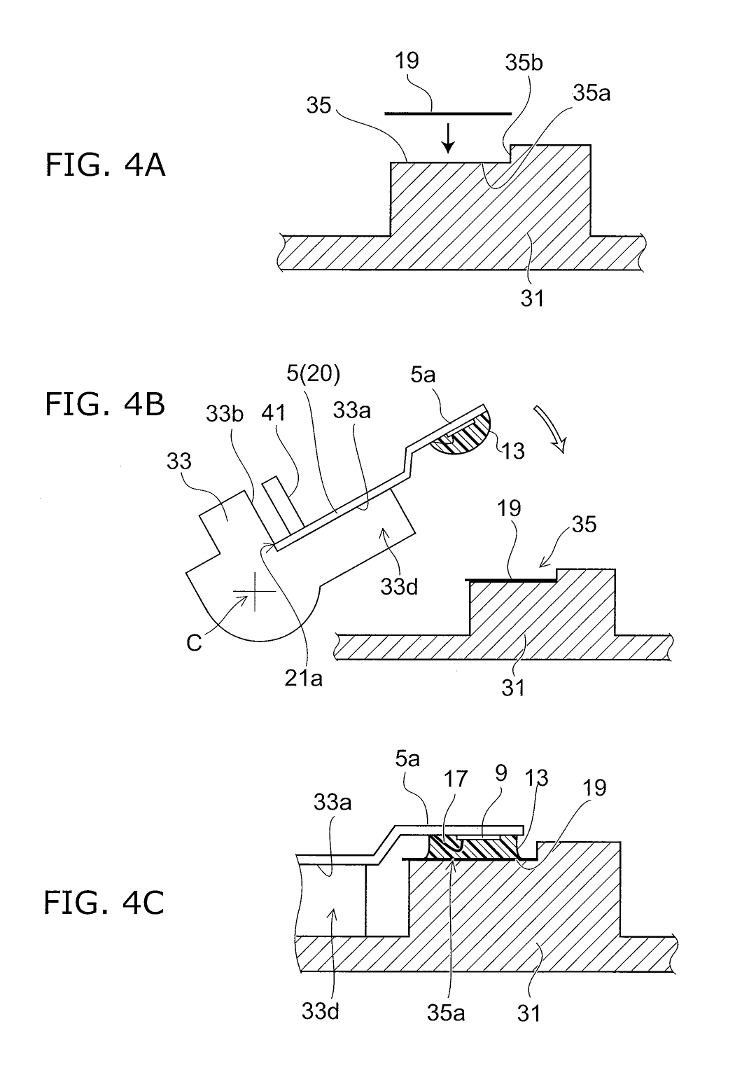

The movable portion 33 includes a first face 33a to which the lead frame 20 is fitted and a second face 33b that is perpendicular to the first face 33a. The lead frame 20 is mounted on the first face 33a in such a way that a side face 21a of the frame 21 is in contact with the second face 33b (see FIG. 4B). Hence, the relative position of the lead frame 20 in the Y direction is fixed with respect to the jig 30.

In addition, the X direction positioning is determined by providing a guide hole 33c in the first face 33a to correspond with a feed hole 22 in the lead frame 20. Thus, the lead frame 20 is fixed with a fixing pin to the first face 33a via the feed hole 22. Hence, the relative position of the lead frame 20 in the X direction is also fixed with respect to the jig 30.

The plurality of pockets 35 in the base portion 31 is provided in a position corresponding to the mount beds 5a of the lead frame 20, which is fixed in a determined position on the movable portion 33. Hence, the lead frame 20 is fixed to the first face 33a and, by rotating the movable portion 33 in the direction of the base portion 31, the mount beds 5a can be set in positions overlapping the pockets 35.

FIGS. 4A to 4C are cross-sectional views schematically illustrating an adhering process of the insulation film 19 using the jig 30.

First, as illustrated in FIG. 4A, the insulation film 19 is mounted in the pocket 35 of the jig 30. The pocket 35 includes a flat portion 35a where the insulation film 19 is mounted and a step 35b that constrains movement of the insulation film 19 in a direction along the flat portion 35a.

Next, as illustrated in FIG. 4B, the lead frame 20 is fixed to the movable portion 33 of the jig 30. The transparent resin 13 that envelops the light receiving element 9 is set on the first face 33a so as to face the base portion 31 side. Then, the frame side face 21a is in contact with the second face 33b and fixed by a fixing pin 41 through the feed hole 22. Consequently, the relative position of the lead frame 20 with respect to the jig 30 is fixed definitively.

Next, the movable portion 33 is rotated around the rotation axis C in the direction of the base portion 31, thereby covering the pockets 35 with the mount beds 5a. As a result, the insulation film 19 makes contact with the transparent resin 13 provided on the surface of the lead frame where the light receiving element 9 is fixedly attached.

As illustrated in FIG. 4C, the arrangement can be configured so that the rotation is stopped by an end 33d of the movable portion 33 being in contact with the base portion 31. At this point, it is preferable that the mount bed 5a and the flat portion 35a of the pocket 35 are substantially parallel. It is then possible to maintain the insulation film 19 and the mount bed 5a in a parallel state.

Further, as illustrated in FIG. 4C, a height of the flat portion of the pockets 35 is set so that the insulation film 19 is distanced from the metal wires 17 that connect the light receiving element 9 and the leads 5. Accordingly, deformation of the metal wires 17 can be prevented.

Next, the transparent resin 13 is cured with the mount beds 5a maintained in a state of covering the pockets 35, and the insulation film 19 is adhered thereto. For example, if the transparent resin 13 is a thermosetting epoxy resin, the transparent resin 13 is cured by inserting the jig 30 into a thermostatic oven set in a temperature range of 100 to 150 degrees centigrade. During this time, the movable portion 33 has been rotated towards the base portion 31 side and a state is maintained whereby the lead frame 20 covers the pocket 35. Thus, the resin can be cured with a constant relative position maintained between the mount bed 5a and the insulation film 19, and misalignment of the insulation film 19 can be suppressed.

Next, the lead frame 20 to which the insulation film 19 is adhered and a lead frame 40 to which the light emitting element 7 is fixedly attached are combined.

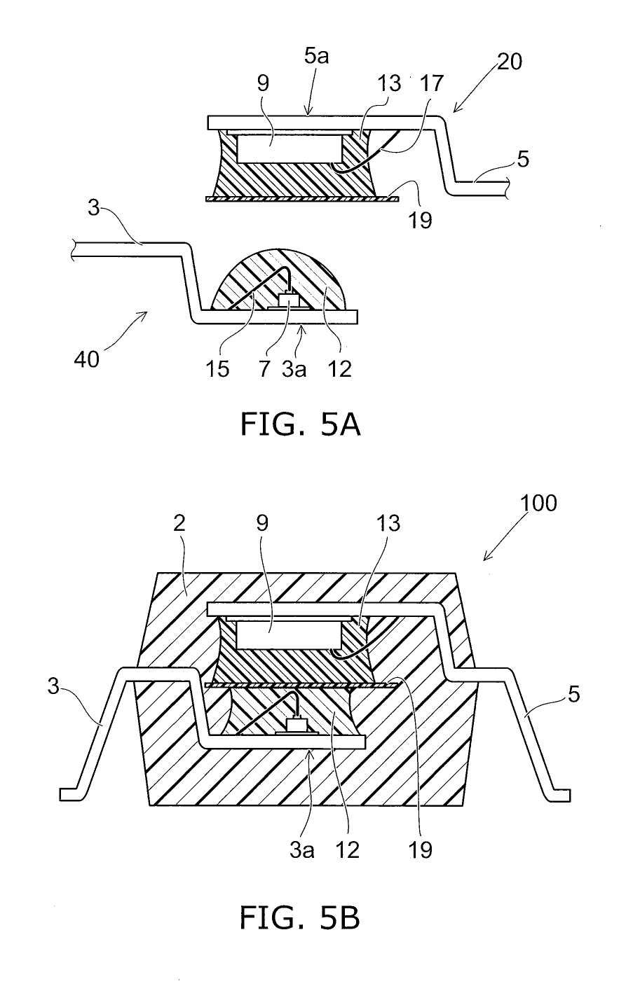

As illustrated in FIG. 5A, the light emitting element 7 fixedly attached to the mount bed 3a is enveloped with the transparent resin 12. For example, the transparent resin 12 may be an epoxy resin, and can be applied using a dispenser. Next, with the light emitting element 7 and the light receiving element 9 set to oppose each other, the lead frame 20 and the lead frame 40 are combined. Curing is then performed with the insulation film 19 in contact with the transparent resin 12 that envelops the light emitting element 7.

Next, as illustrated in FIG. 5B, the molded body 10 is formed to envelop the end portion of the lead 3 to which the light emitting element 7 is fixedly attached, the end portion of the lead 5 to which the light receiving element 9 is fixedly attached, the transparent resins 12 and 13 and the insulation film 19. Next, the semiconductor device 100 is completed by processing to bend the leads 3 and 5 and separating the individual molded bodies from the frame.

The molded body 10 is, for example, formed from a black resin that shields against external light. For the black resin, an epoxy resin including carbon or the like can be used. Alternatively, a white resin that reflects external light may be used.

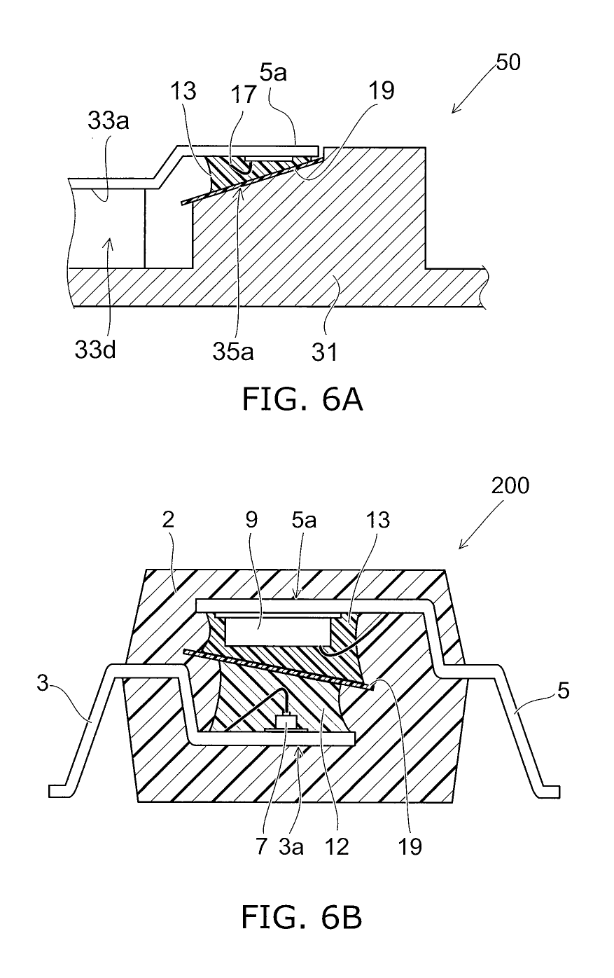

FIGS. 6A and 6B are schematic views illustrating a jig 50 according to a variation of the embodiment. FIG. 6A is a schematic cross-sectional view illustrating a state in which the mount beds 5a of the lead frame 20 are positioned covering the pockets 35. FIG. 6B is a schematic view illustrating a cross section of a semiconductor device 200 manufactured using the jig 50.

The jig 50 illustrated in FIG. 6A differs from the jig 30 illustrated in FIGS. 3A and 3B in that the flat portion 35a of the pocket 35 is formed to be inclined. The insulation film 19 is mounted on the flat portion 35a of the pocket 35, and contacts the mount beds 5a along the incline. In this case, it is preferable that the height of the flat portion 35a is set so that the insulation film 19 is distanced from the metal wires 17. With such an arrangement deformation of the metal wires 17 can be prevented.

As illustrated in FIG. 6B, when the jig 50 is used, the insulation film 19 is interposed obliquely between the light emitting element 7 and the light receiving element 9. The angle of inclination with respect to the mount beds 5a or 3a can be freely set by altering the inclination of the flat portion 35a of the pocket 35. Thus, the angle of inclination can be set to be appropriate for the arrangement of the light emitting element 7 and the light receiving element 9, a form of the package (external form of the molded body 10), or the like.

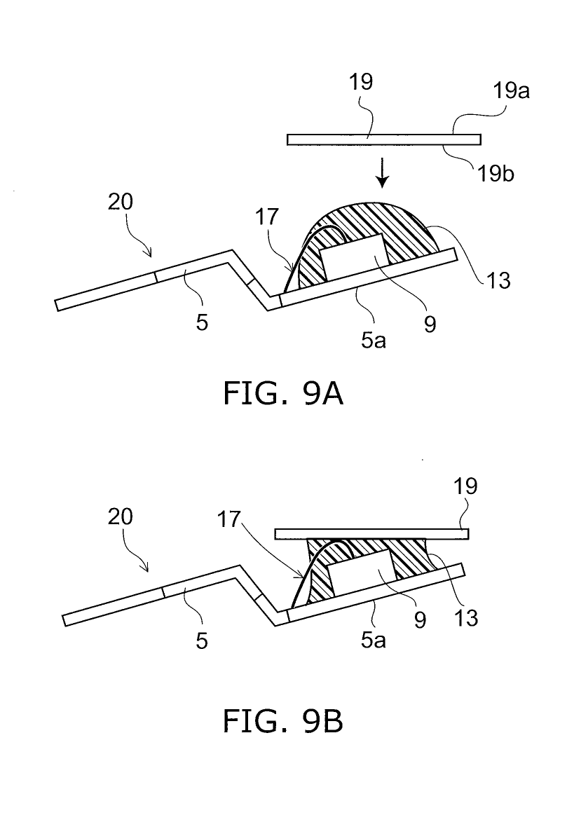

FIGS. 9A and 9B are schematic views illustrating a manufacturing process of a semiconductor device according to a comparative example. In the comparative example, the insulation film 19 is adhered without using a jig.

As illustrated in FIG. 9A, the light receiving element 9 is fixedly attached to the mount bed 5a and enveloped with the transparent resin 13. The insulation film 19 is then mounted on the transparent resin 13. Next, pressure is applied to the front surface 19a of the insulation film 19 by blowing air or the like, causing the transparent resin 13 to adhere to a back surface 19b of the insulation film 19.

As illustrated in FIG. 9B, the insulation film 19 is in contact with the top portion of the looped metal wires 17 that connect the light receiving element 9 to the terminals. The insulation film 19 is adhered so as to be inclined with respect to the mount bed 5a and with the top portion of the metal wires 17 as a point of support.

In the above-described manufacturing process, an extremely thin transparent resin 13 may be interposed between the insulation film 19 and the metal wires 17. In this and similar cases, the insulation film 19 is described as being in contact with the metal wires 17. This is to be distinguished from the state in which the insulation film 19 is distanced from the metal wires 17.

Consequently, as in the semiconductor device 200 illustrated in FIG. 6B, a structure is formed whereby the insulation film 19 is interposed obliquely between the light emitting element 7 and the light receiving element 9. However, in the manufacturing method according to the comparative example where the jig is not used, it is difficult to control the angle of inclination between the insulation film 19 and the mount beds 5a. Also, deformation of the metal wires 17 and misalignment can occur easily in the relative position of the insulation film 19 and the mount bed 5a.

By contrast, in the manufacturing method according to this embodiment, by using the jigs 30 and 50, deformation of the metal wires 17 can be prevented and the relative position and inclination of the insulation film 19 can be kept uniform. Consequently, the quality of the semiconductor devices 100 and 200 can be stabilized. Moreover, as described below, the misalignment of the insulation film 19 can be kept within a predetermined range.

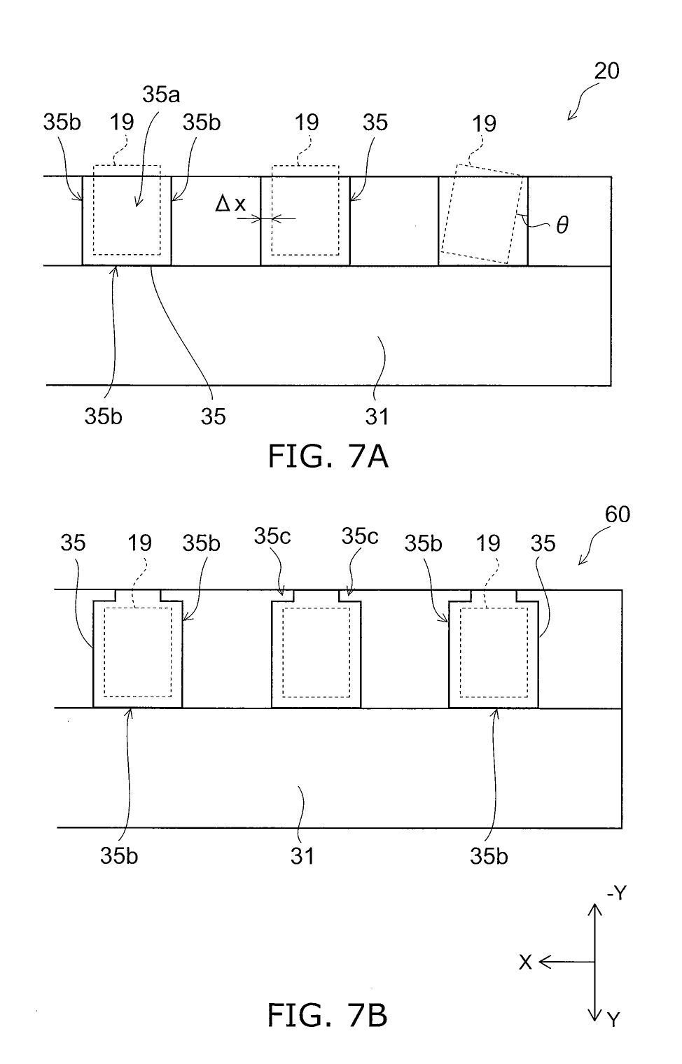

FIG. 7A is a plan view schematically illustrating the pockets 35 of the jigs 30 and 50. FIG. 7B is a plan view illustrating the pockets 35 of the jig 60 according to a modification example.

As illustrated in FIG. 7A, the pockets 35 include flat portions 35a which are provided to match the external form of the insulation film 19 and a step 35b provided on three sides of each flat portion 35a.

The movement in the Y direction of the insulation film 19 mounted on the flat portion 35a is constrained by the step 35b. On the other hand, in the −Y direction, which is the opposite direction to the Y direction, the insulation film 19 can move freely. In the X direction, the step 35b provided on both sides constrains the movement within the range ±Δx. Moreover, the rotational angle θ in the X-Y plane is constrained by the X direction tolerance Δx. Hence, by setting the X direction tolerance Δx to be, for example, less than or equal to the misalignment tolerance, it is possible to reduce the occurrence of defects caused by misalignment of the insulation film 19.

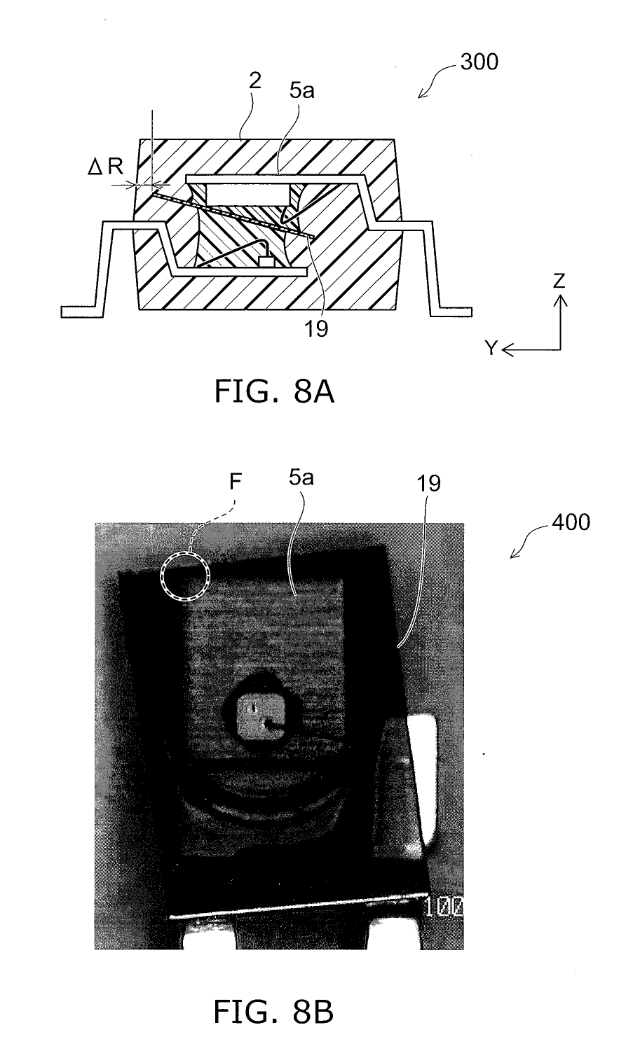

FIG. 8A and FIG. 8B schematically illustrate misalignment of the insulation film 19 in semiconductor devices 300 and 400 according to comparative examples.

For example, when the edge of the insulation film 19 approaches the external face of the molded body 10, stress may be generated at that portion and cracking may occur in the light shielding resin 2. Hence, it is preferable that a gap ΔR, illustrated in FIG. 8A, between the external face of the molded body 10 and the edge of the insulation film 19 is controlled to at least a predetermined value. A movement of the insulation film 19 in the Y direction causes misalignment, narrowing ΔR. Hence, as illustrated in FIG. 7A, the step 35b that constrains the movement towards the Y direction is provided. Consequently, it is possible to maintain ΔR at a predetermined value or wider and to suppress the occurrence of cracking of the molded body 10.

On the other hand, since a gap between the opposite end of the insulation film 19 and the external face of the molded body 10 in the −Y direction (the direction which widens ΔR) is large, the tolerance here is large. Hence, in the pockets 35 illustrated in FIG. 7A, there is no need to provide a means to constrain movement in the −Y direction. As a result, it is easy to mount the insulation film 19 in the pockets 35.

FIG. 8B is an example in which the insulation film 19 has rotated in the X-Y plane to generate misalignment in the θ direction.

For example, at the portion marked F in FIG. 8B, a gap between the mount bed 5a and the edge of the insulation film 19 may be narrower due to misalignment of the insulation film 19 in the θ direction. In such a state, a width of a portion extending from the transparent resin 13 of the insulation film 19 narrows at the position F. Hence, the extended surface distance between the lead 3 and the lead 5 is shortened and a drop in the isolation voltage between the primary side and secondary side may occur.

In the jigs 30 and 50 according to this embodiment, the tolerance Δx in the X direction is constrained to a predetermined value and it is thereby possible to suppress misalignment in the θ direction and thus to suppress reduction in the isolation voltage.

Further, as illustrated in FIG. 7B, the step 35c may be provided to constrain movement of the insulation film 19 in the −Y direction. This enables tight control of the position at which the insulation film 19 is interposed.

As described above, in the method for manufacturing the semiconductor device according to the embodiment, use of the jigs 30 and 50 allows the insulation film 19 to be accurately adhered to the mount beds 5a to which the light receiving elements 9 are fixedly attached. Consequently, misalignment of the insulation film 19 can be suppressed and manufacturing yield of the semiconductor device can be increased. Further, by using the jigs 30 and 50, operability in the process to adhere the insulation film is improved and production efficiency can be increased.

Note that while in the above-described embodiments, the movable portion 33 in the jigs 30 and 50 was described as rotating with respect to the base portion 31, this is not limiting. For instance, the movable portion 33 may be configured so as to slide relative to the base portion 31. Alternatively, a configuration may be used whereby the movable portion 33 is separated and reengaged after fixing the lead frame 20 to allow the mount beds 5a to cover the pockets 35.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a semiconductor device, the method comprising:
enveloping a semiconductor chip attached to a lead frame with a resin;
mounting a film-like member in a pocket provided in a base portion of a jig;
making the resin in contact with the film-like member by covering the pocket with the portion of the lead frame having the semiconductor chip fixed thereto, after fixing the lead frame to a movable portion of the jig and moving the movable portion in a direction of the base portion; and
curing the resin with the lead frame in a state covering the pocket.

2. The method according to claim 1, wherein the film-like member is kept in parallel to a front surface of the lead frame while the lead frame is covering the pocket.

3. The method according to claim 1, wherein the semiconductor chip is electrically connected to the lead frame via a metal wire, and the film like member is distanced from the metal wire, while the lead frame is covering the pocket.

4. The method according to claim 1, wherein
the lead frame has a plurality of mount beds aligned in one direction;
the semiconductor chip is attached to each of the mount beds; and
each of the mount beds covers corresponding one of a plurality of pockets provided in the base portion.

5. The method of claim 4, wherein the mount beds are set parallel to flat portions of the pockets where the film-like members are mounted, and the film-like member is adhered parallel to the mount bed.

6. The method according to claim 4, wherein the mount beds are inclined at a predetermined angle with respect to flat portions of the pockets where the film-like member is mounted, and the film-like member is adhered to the mount bed at the predetermined angle.

7. The method according to claim 1 wherein the semiconductor chip is a light receiving element, and the light receiving element is enveloped with a transparent resin.

8. The method according to claim 7, further comprising:
joining one lead frame with the other lead frame, the light receiving element being attached and the film-like member being fixedly adhered to the one lead frame, and a light emitting element enveloped with a transparent resin being attached to the other lead frame; and
forming a molded body enveloping the light receiving element, the light emitting element and the film-like member.

9. The method according to claim 8, wherein the molded body is formed from a resin that shields against external light.

10. A jig comprising:
a base portion having a pocket, a film-like member being mounted on the pocket; and
a movable portion rotatably attached to the base portion, a lead frame being able to be fixed thereto,
wherein the movable portion rotates to the pocket side with the lead frame so that a portion of the lead frame covers the pocket.

11. The jig according to claim 10, wherein the pocket includes a flat portion where the member is mounted and a step for constraining movement of the member in a direction along the flat portion.

12. The jig according to claim 11, wherein the pocket includes the flat portion that fits an external form of the film-like member and the step is provided on a periphery of the flat portion.

13. The jig according to claim 10, wherein the base portion includes a plurality of the pockets aligned in one direction.

14. The jig according to claim 10, wherein the movable portion includes a first face, the lead frame being fitted thereto, and a second face perpendicular to the first face, an end face of the lead frame being in contact therewith.

15. The jig according to claim 10, further comprising a guide hole for inserting a fixing pin to fix the lead frame.

16. The jig according claim 10, wherein the movable portion includes a portion being in contact with the base portion and stopping the rotation.
